(19) United States
(12) Patent Application Publication
(10) Pub. No.: US 2023/0098433 A1
(43) Pub. Date: Mar. 30, 2023

(54) Subtractive Skip-Level Power via Adjacent Recessed Damascene Signal Lines

(71) Applicant: International Business Machines Corporation, Armonk, NY (US)

(72) Inventors: Nicholas Anthony Lanzillo, Wynantskill, NY (US); Huai Huang, Clifton Park, NY (US); Hosadurga Shobha, Niskayuna, NY (US); Lawrence A. Clevenger, Saratoga Springs, NY (US)

(73) Assignee: International Business Machines Corporation

(21) Appl. No.: 17/486,120

(22) Filed: Sep. 27, 2021

(51) Int. Cl. H01L 21/768; H01L 23/522; H01L 23/528

(52) U.S. Cl. CPC H01L 21/76816; H01L 23/5226; H01L 23/5286; H01L 21/76877; H01L 21/76807

(57) ABSTRACT

An interconnect stack structure includes a first metal level of horizontal power line wiring; a second metal level of horizontal power line wiring; wherein the first metal level is not adjacent to the second metal level; two top-via structures comprising a first via and a second via, the two top-via structures being formed above the first metal level; wherein the first via has a first height and the second via has a second height, the first height being different from the second height; wherein the first via extends to connect the first metal level to the second metal level; wherein the second via extends to connect to the first metal level but not the second metal level; damascene intermediate metal lines between the first metal level and the second metal level; and damascene signal lines above the first via and the damascene intermediate metal lines.

### BACKGROUND

The exemplary embodiments described herein relate generally to chip design and power processor grids, and methods for the fabrication thereof and, more specifically, to a subtractive skip-level power via with adjacent recessed damascene signal lines.

### BRIEF SUMMARY

In one aspect, an interconnect stack structure includes a first metal level of horizontal power line wiring; a second metal level of horizontal power line wiring; wherein the first metal level of horizontal power line wiring is not adjacent to the second metal level of horizontal power line wiring; two top-via structures comprising a first via and a second via, the two top-via structures being formed above the first metal level of horizontal power line wiring; wherein the first via has a first height and the second via has a second height, the first height being different from the second height; wherein the first via extends to connect the first metal level of horizontal power line wiring to the second metal level of horizontal power line wiring; wherein the second via extends to connect to the first metal level but not the second metal level; damascene intermediate metal lines between the first metal level of horizontal power line wiring and the second metal level of horizontal power line wiring; and damascene signal lines above the first via and the damascene intermediate metal lines.

In another aspect, a power delivery network structure includes a first power rail; a second power rail; wherein the first power rail and the second power rail are connected by a skip-level via; wherein there are no power islands between the first power rail and the second power rail; a plurality of damascene signal lines located between the first power rail and the second power rail; a plurality of top-via structures below the plurality of damascene signal lines and above the first power rail; wherein the plurality of top-via structures comprise at least the skip-level via; and a plurality of damascene via structures located above the plurality of damascene signal lines.

In another aspect, a method includes subtractively forming a first via with a first height and a second via with a second height, the first height being greater than the second height; wherein the first via and second via are formed above a first metal power line; forming a metal layer signal line above the second via; forming a metal layer recess above the first metal layer signal line by removing a part of the first metal layer signal line; forming a plurality of damascene signal lines above the first via and the metal layer recess; forming a plurality of damascene via structures above the plurality of damascene signal lines; and forming a second metal power line above the plurality of damascene via structures.

### BRIEF DESCRIPTION OF THE SEVERAL VIEWS OF THE DRAWINGS

The foregoing and other aspects of exemplary embodiments are made more evident in the following Detailed Description, when read in conjunction with the attached Drawing Figures, wherein:

FIG. 1 is a cross-sectional view of a power rail line;

FIG. 2 is a cross-sectional view of a power rail line with one via interface;

FIG. 3 illustrates an example process flow, based on embodiments described herein.

FIG. 4 shows a first method for how to form subtractive vias with different heights;

FIG. 5 shows a second method for how to form subtractive vias with different heights;

FIG. 6 shows an overview of a process flow, based on the examples described herein;

FIG. 7A shows a portion of a process flow along an M1 power line, including a blanket metal deposition application;

FIG. 7B shows a portion of the process flow along the M1 power line, including metal etch and supervia formation;

FIG. 7C shows a portion of the process flow along the M1 power line, including dielectric deposition application and chemical mechanical polishing (CMP);

FIG. 7D shows a portion of the process flow along the M1 power line, including an M2 signal line etch;

FIG. 7E shows a portion of the process flow along the M1 power line, including M2 metallization and CMP;

FIG. 7F shows a portion of the process flow along the M1 power line, including formation of an M2 metal recess;

FIG. 7G shows a portion of the process flow along the M1 power line, including dielectric deposition application;

FIG. 7H shows a portion of the process flow along the M1 power line, including an M3 lithography and etch;

FIG. 7I shows a portion of the process flow along the M1 power line, including M3 metallization;

FIG. 8A shows a portion of a process flow along an M1 signal line, including blanket metal deposition application;

FIG. 8B shows a portion of the process flow along the M1 signal line, including a metal etch to form M1 and V1;

FIG. 8C shows a portion of the process flow along the M1 signal line, including dielectric deposition application;

FIG. 8D shows a portion of the process flow along the M1 signal line, including M2 lithography and etch;

FIG. 8E shows a portion of the process flow along the M1 signal line, including M2 metallization;

FIG. 8F shows a portion of the process flow along the M1 signal line, including formation of an M2 metal recess;

FIG. 8G shows a portion of the process flow along the M1 signal line, including dielectric deposition application;

FIG. 8H shows a portion of the process flow along the M1 signal line, including a V2M3 lithography/etch;

FIG. 8I shows a portion of the process flow along the M1 signal line, including V2M3 metallization and CMP;

FIG. 9A shows a portion of a process flow along an M2 power island, including blanket metal deposition application;

FIG. 9B shows a portion of the process flow along the M2 power island, including M1 metal line and supervia formation;

FIG. 9C shows a portion of the process flow along the M2 power island, including dielectric deposition application;

FIG. 9D shows a portion of the process flow along the M2 power island, including an M3 lithography/etch;

FIG. 9E shows a portion of the process flow along the M2 power island, including M3 metallization;

FIG. 10A shows a portion of a process flow along an M2 signal line, including blanket metal deposition application;

FIG. 10B shows a portion of the process flow along the M2 signal line, including M1 metal line and V1 formation;

FIG. 100 shows a portion of the process flow along the M2 signal line, including dielectric deposition application;

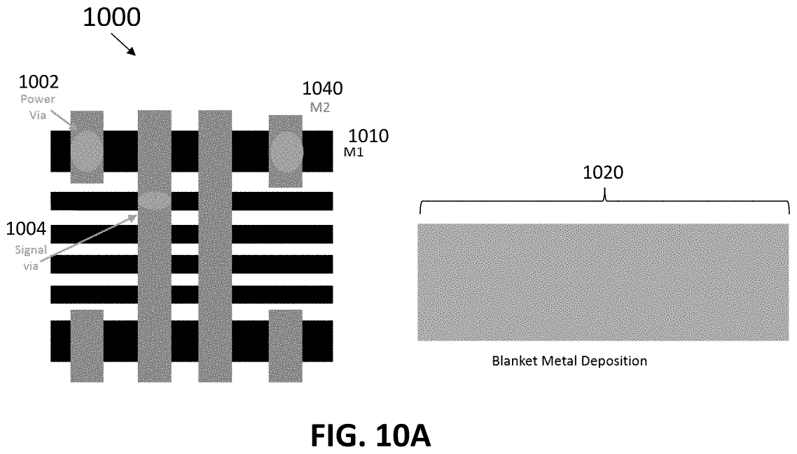

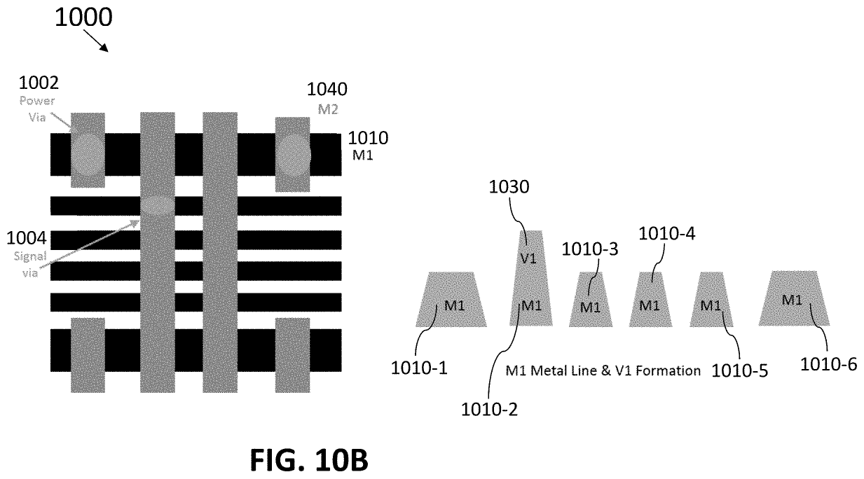

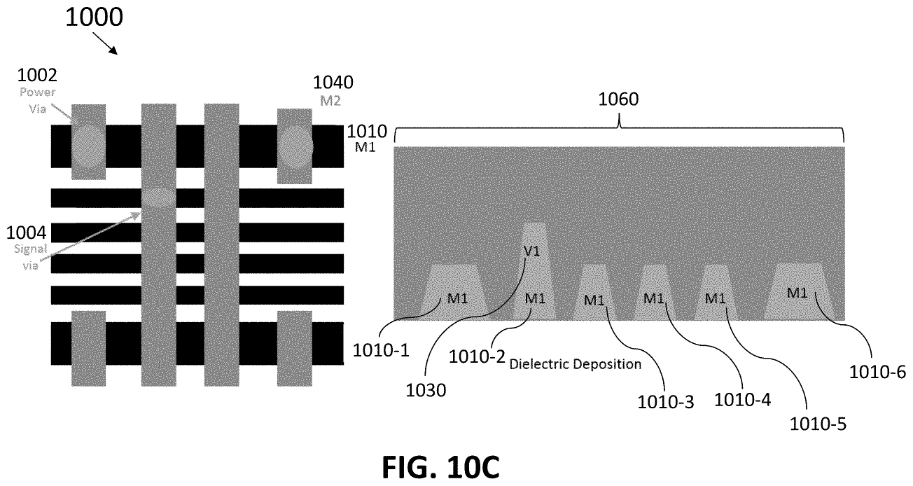

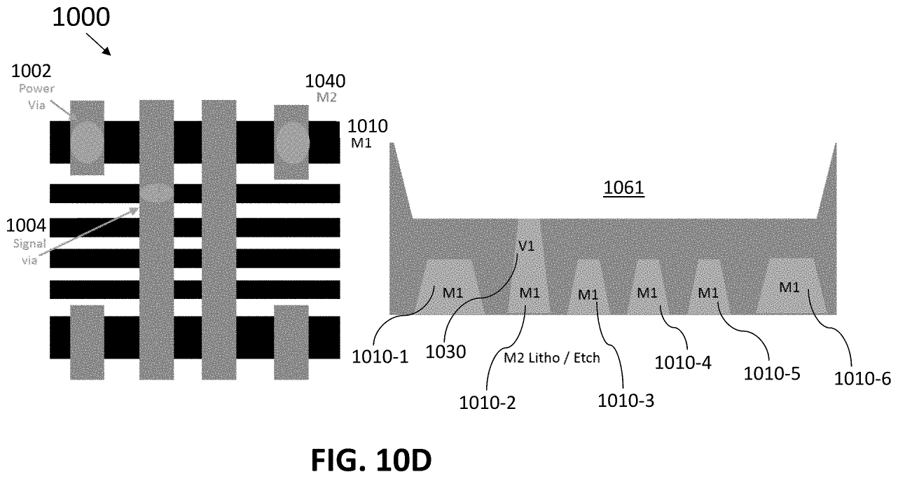

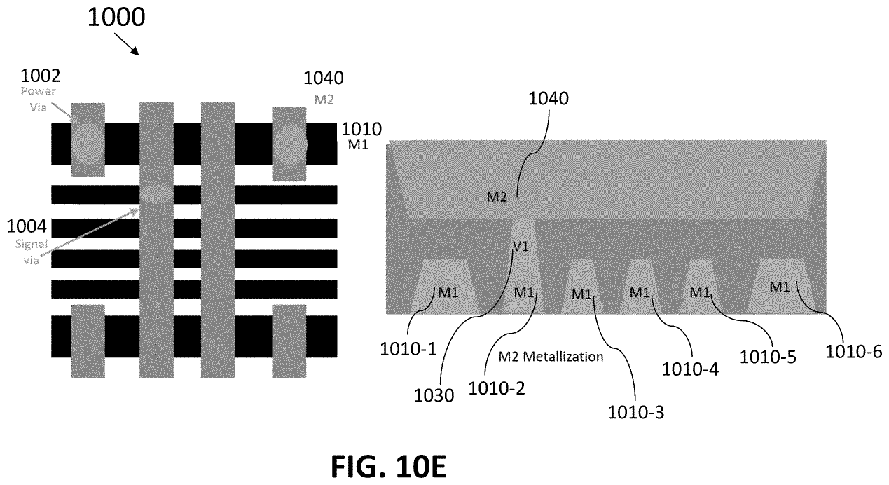

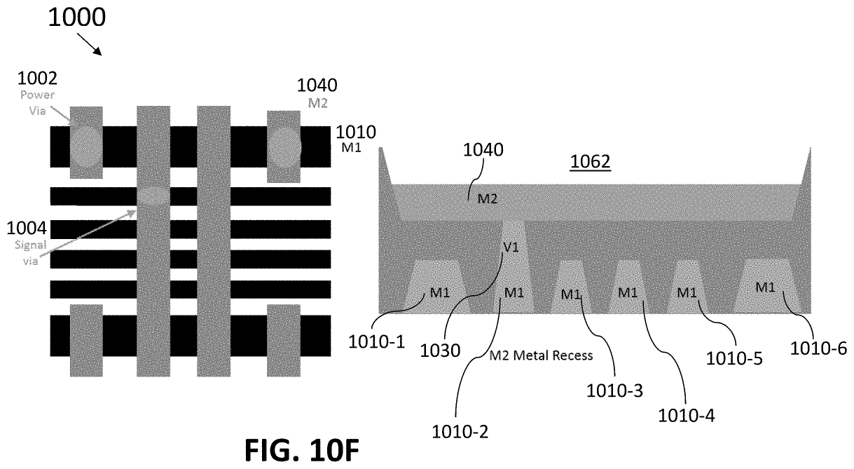

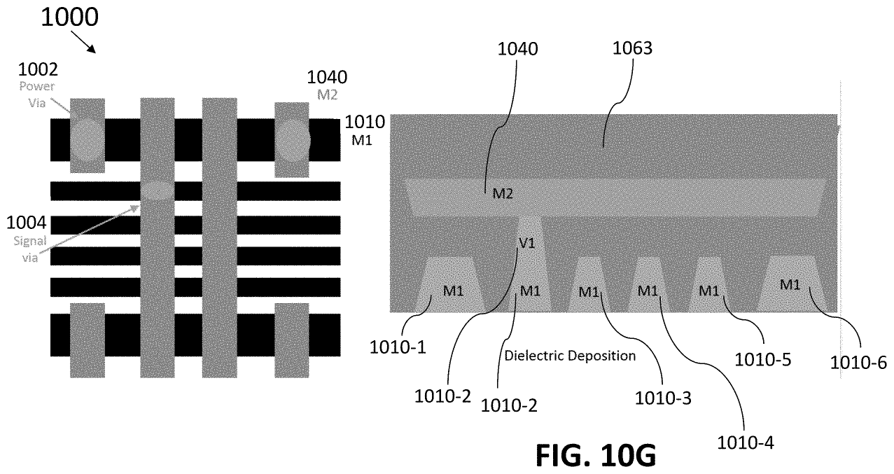

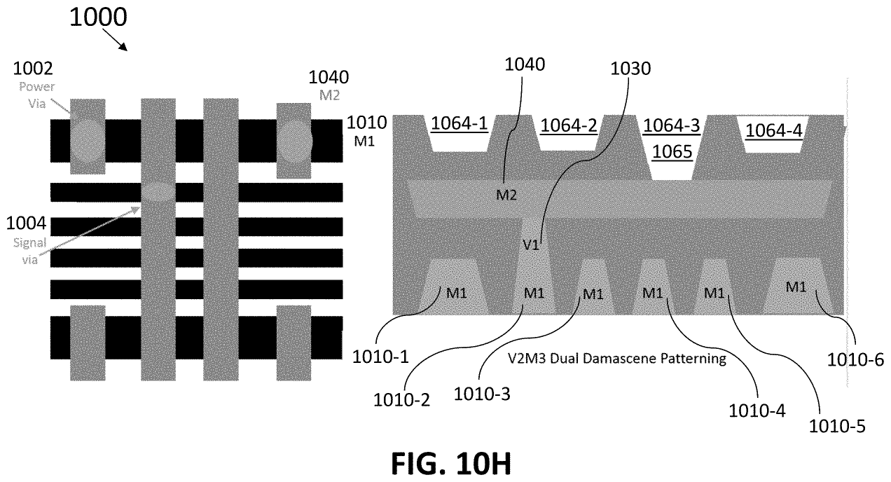

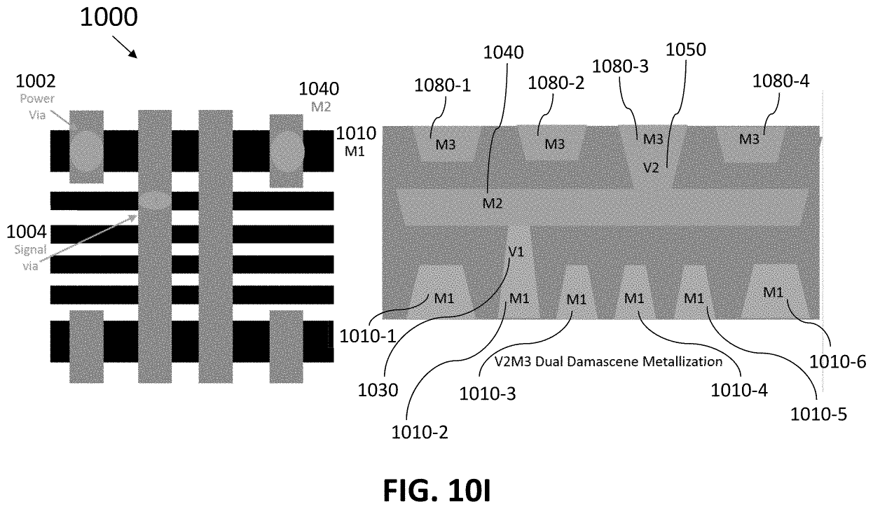

FIG. 10D shows a portion of the process flow along the M2 signal line, including an M2 lithography/etch;

FIG. 10E shows a portion of the process flow along the M2 signal line, including M2 metallization;

FIG. 10F shows a portion of the process flow along the M2 signal line, including formation of an M2 metal recess;

FIG. 10G shows a portion of the process flow along the M2 signal line, including dielectric deposition application;

FIG. 10H shows a portion of the process flow along the M2 signal line, including V2M3 dual damascene pattering;

FIG. 10I shows a portion of the process flow along the M2 signal line, including V2M3 dual damascene metallization; and

FIG. 11 is a logic flow diagram that illustrates the operation of an exemplary method, and a result of execution of computer program instructions embodied on a computer readable memory, in accordance with an exemplary embodiment of the methods for forming the structures described herein.

### DETAILED DESCRIPTION

The term “exemplary” is used herein to mean “serving as an example, instance, or illustration.” Any embodiment described herein as “exemplary” is not necessarily to be construed as preferred or advantageous over other embodiments. All of the embodiments described in this Detailed Description are exemplary embodiments provided to enable persons skilled in the art to make or use the invention and not to limit the scope of the invention which is defined by the claims.

The abbreviation V is used herein generally as an abbreviation for via, and the abbreviation M is used generally as an abbreviation for metal layer. For example, M1 corresponds to metal one, or a first metal layer, M2 corresponds to metal two, or a second metal layer, and so on.

Power rails are typically implemented with two via interfaces, and adherence to M2 power island minimum area rules puts routing pressure on M2 signal lines.

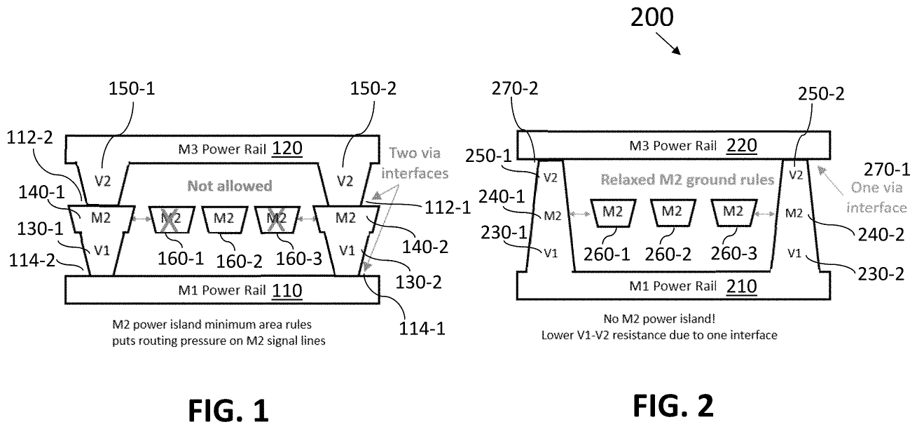

FIG. 1 shows a cross-sectional view of a power rail line. In the structure, shown in FIG. 1, M2 power island minimum area rules put routing pressure on M2 signal lines. The M2 power island minimum area restricts via access to M2 lines, resulting in significant routing pressure and reduced pin access. Further, the M2 power islands restrict density scaling and also result in high V1-M1-V2 resistance for power vias. FIG. 1 shows an M1 power rail 110 coupled to the M3 power rail 120 with two via interfaces 112-1 and 114-1 (shown are symmetrically located two via interfaces 112-2 and 114-2). The M1 power rail 110 is further coupled to the M3 power rail 120 using V1 (130-1, 130-2), M2 (140-1, 140-2), and V2 (150-1, 150-2). There is an M2 power island 160-2, however the structure shown in FIG. 1 does not allow the M2 power island 160-1 to be bidirectionally coupled to the M2 140-1, and does not allow the M2 power island 160-3 to be bidirectionally coupled to the M2 140-2.

FIG. 2 therefore shows a new structure 200, as described herein, where there is no M2 power island and one via interface 270-1 (there is a symmetrically located via interface 270-2). The new structure as shown in FIG. 2 has lower V1-V2 resistance due to the one interface 270-1, and relaxed M2 ground rules. FIG. 2 shows an M1 power rail 210 coupled to the M3 power rail 220 with the one via interface 270-1. The M1 power rail 210 is further coupled to the M3 power rail 220 using V1 (230-1, 230-2), M2 (240-1, 240-2), and V2 (250-1, 250-2). Thus the new structure includes two top-via structures (on top of M1 power rail 210), including: a first top-via structure comprising V1 230-1, M2 240-1, and V2 250-1, and a second top-via structure comprising V1 230-2, M2 240-2, and V2 250-2.

FIG. 2 further shows that the new structure includes M2 power islands 260-1, 260-2, and 260-3. Due to the relaxed M2 ground rules provided by the new structure shown in FIG. 2, the new structure allows the M2 power island 260-1 to be bidirectionally coupled to M2 240-1, and allows the M2 power island 260-3 to be bidirectionally coupled to M2 240-2. Thus, the new structure shown in FIG. 2 provides increased via access to M2 due to relaxed ground rules.

The benefits of the new structure shown in FIG. 2 include that for power processor design, V1-V2 power vias account for a net 2.4% of total chip delay. Reducing V1-V2 resistance by 50% results in a net 1.2% chip performance. The relaxed M2 ground rules allow for more M2 signal tracks to be placed between power islands. For a 6-track library, one additional M2 routing line increases routing utilization by 17%.

In power processor chip design, V1/V2 stacked power vias account for 2.5% of total photoplethysmography (PPG) delay. Eliminating a via interface reduces via resistance by approximately 50%, resulting in a net 1-1.5% performance uplift. Elimination of M2 power islands results in a relaxation of M2 ground rules, and increases M2 signal line utilization.

Accordingly, described herein is a structure with subtractively-formed top vias having different heights. The described structure has a subtractively-formed skip-level power via adjacent to buried damascene signal lines. The described structure provides for elimination of M2 power islands.

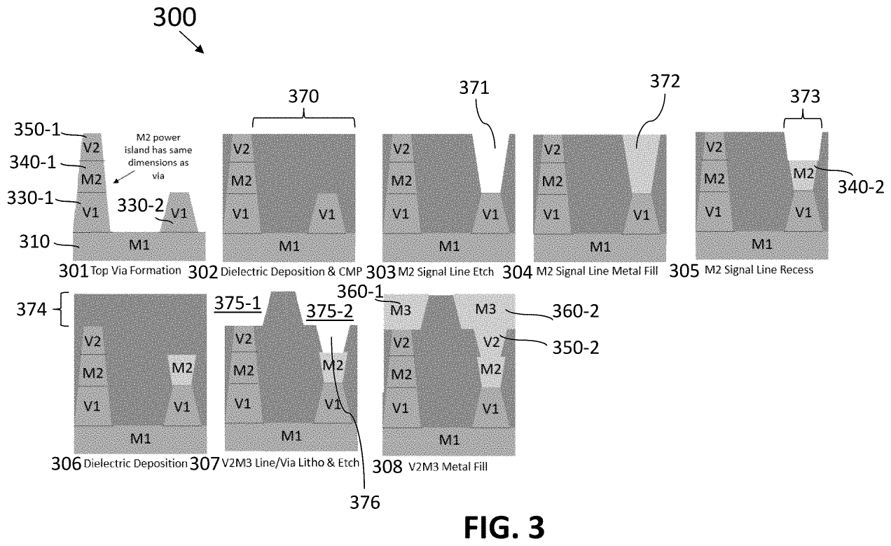

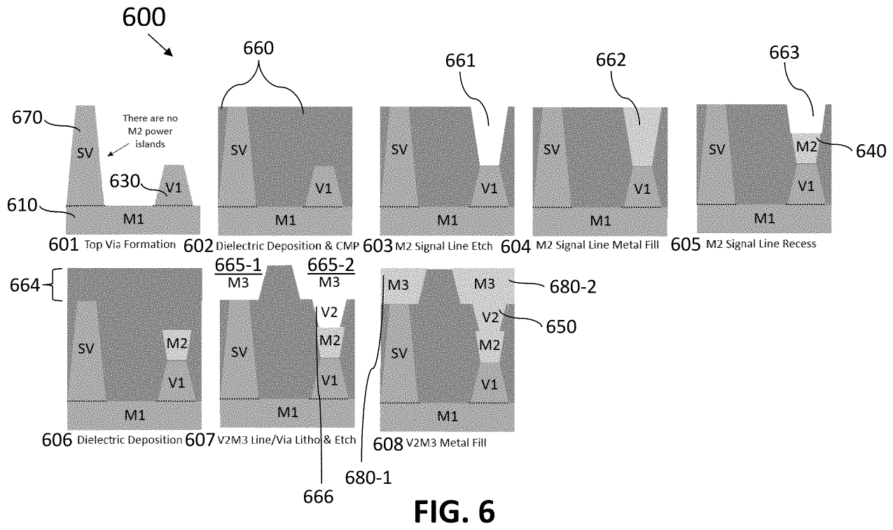

FIG. 3 illustrates an example process flow 300, based on embodiments described herein. Item 301 of the process shows top via formation. V1 330-1 and V1 330-2 are fabricated on the surface of the M1 power island 310, with M2 340-1 fabricated onto the surface of V1 330-1, and V2 350-i fabricated onto the surface of M2 340-1. The M2 power island 340-1 has the same dimensions as the via. V1 330-1, M2 340-1, and V2 350-1 from a supervia structure, similar to SV 670 shown in FIG. 6. Item 302 of the process shows dielectric deposition 370 application and CMP. Item 303 of the process shows the M2 signal line etch 371, the M2 signal line etch 371 being etched into the dielectric deposition 370 such that the M2 signal line can be formed adjacent to the surface of V1 330-2. Item 304 of the process shows the M2 signal line metal fill 372. Item 305 of the process shows the M2 power island 340-2 fabricated within the M2 signal line metal fill 372, as well as the M2 signal line recess 373 formation. Item 306 of the process shows application of a second dielectric deposition 374, above the surface of V2 350-1. Item 307 of the process shows a V2M3 line/via lithography and etch. Item 307 shows two M3 signal line etches (375-1 and 375-2), etched within the second dielectric deposition 374, such that two M3 power islands may be fabricated onto surfaces of V2 350-1 and V2 350-2, respectively. Item 307 further shows the V2 via etch 376, etched within the dielectric deposition 370 and/or the second dielectric deposition 374, such that V2 350-2 may be fabricated onto the surface of M2 340-2 as well as under and contacting the surface of M3 360-2. Item 308 of the process shows the V2M3 metal fill. Particularly, item 308 of the process shows V2 350-2 being fabricated within the V2 etch 376, and the M3 power islands 360-1 and 360-2 being fabricated within the M3 etches 375-1 and 375-2, respectively.

As described herein, disclosed is a power delivery network with M(x) and M(x+2) power rails connected by a subtractively-formed skip-level via, with no M2 power islands. Buried damascene signal lines are located between the M(x) and M(x+2) power rails. Buried damascene signal lines have “top-via” structures located below and damascene via structures located above.

As further described herein, disclosed is a method for formation of subtractively-patterned vias above a metal power line. The method includes a dielectric backfill and a chemical mechanical polishing. The method further includes a signal line trench lithograph, etch and metallization. The method further includes a metal recess of damascene signal lines followed by dielectric deposition. The method further includes a top metal level lithography, etch and metallization for both signal and power lines.

The examples described herein provide several technical effects and value attributes. Technical effects provided by the examples described herein include co-integration of subtractive and damascene features at the same metal level and within the same standard cell library. Further technical effects and value attributes include elimination of M2 power islands, subtractive vias with different heights, and skip-level vias for the power grid only, where signal lines are dual damascene. Further provided and described herein is a buried damascene line in which a metal line is recessed and the area above is filled with dielectric prior to a next-level lithography/etch.

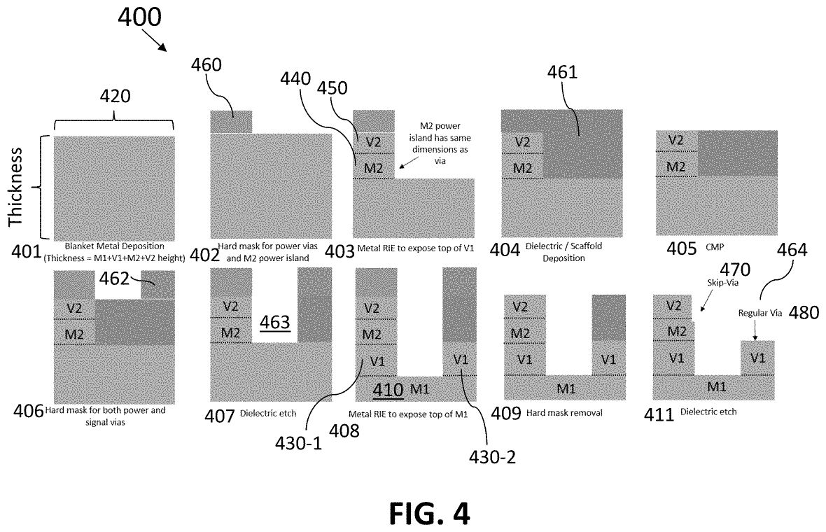

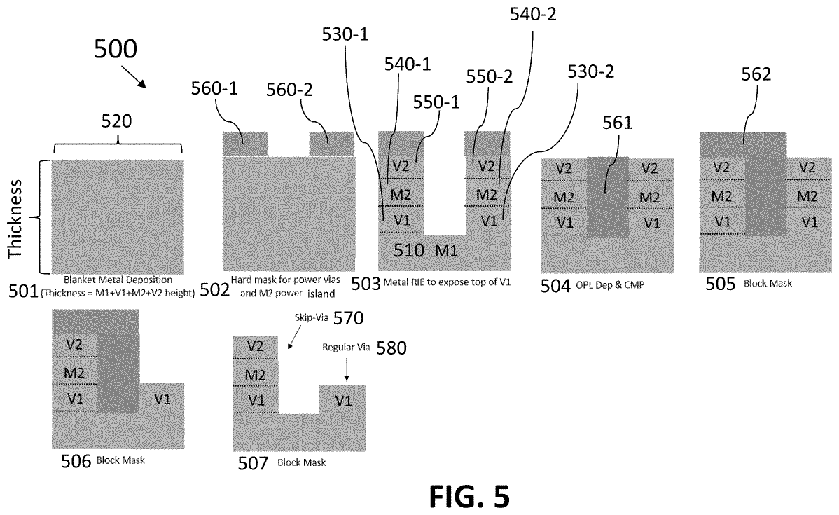

Described herein are two methods (shown in FIG. 4 and FIG. 5) for forming two subtractive vias (one skip-level via, one regular via) at the same level.

FIG. 4 shows a first method 400 for forming subtractive vias with different heights. Item 401 of the method is application of a blanket metal deposition 420. The thickness of the blanket metal deposition is equal to the combined height of M1 410, V1 (430-1 or 430-2), M2 440, and V2 450. Item 402 of the method includes application/fabrication of a hard mask 460 for power vias (430-1 and 450) and for an M2 power island 440. Item 403 of the method includes a metal reactive-ion etching (RIE) to expose the top of V1 430-1, as well as formation of M2 440 and V2 450. In an embodiment, the M2 power island 440 has the same dimensions as the via 450. Item 404 of the method includes application of a dielectric/scaffold deposition 461. Item 405 of the method is CMP which includes removing a portion of the dielectric/scaffold deposition 461 above V2 450, as shown.

Item 406 of the method 400 includes application/fabrication of a hard mask 462 for both power and signal vias, including V1 430-2. Item 407 of the method includes a dielectric etch 463, to etch into a portion of the dielectric/scaffold deposition 461. Item 408 of the method includes a metal RIE to expose the top of M1 410, and formation of V1 430-1 and V1 430-2. Item 409 of the method includes hard mask removal, including removal of hard mask 460 and hard mask 462. Item 411 of the method includes a dielectric etch 464, including further removal of the dielectric/scaffold deposition 461. As a result of method 400, subtractively formed are the skip via 470 having a first height and the regular via 480 having a second height, where the first height is greater than the second height.

FIG. 5 shows a second method 500 for forming subtractive vias with different heights. Item 501 of the method includes application of a blanket metal deposition 520. The thickness of the blanket metal deposition 520 is equal to a combined height, the combined height being equal to the heights of M1 510, V1 (530-1 or 530-2), M2 (540-1 or 540-2), and V2 (550-1 or 550-2). Item 502 of the method includes application of a hard mask (560-1, 560-2) for the power vias (530-1, 530-2, 550-1, 550-2) and the M2 power island (540-1, 540-2). Item 503 of the method includes a metal RIE to expose the top of V1 (530-1, 530-2), as well as the formation of M2 (540-1, 540-2) and V2 (550-1, 550-2) on top of V1 (530-1, 530-2). As shown, M2 (540-1, 540-2) is formed on top of and contacts a surface of V1 (530-1, 530-2), and V2 (550-1, 550-2) is formed on top of and contacts a surface of M2 (540-1, 540-2).

Item 504 of the method includes application of an organic planarization layer (OPL) deposition 561 and CMP, the OPL deposition 561 being applied between V1 530-1 and V1 530-2, between M2 540-1 and M2 540-2, and between V2 550-1 and V2 550-2. Item 505 of the method includes application of a block mask 562 to a surface of V2 550-1 and to the OPL deposition 561. Item 506 of the method includes application of a block mask, including to remove M2 540-2 and V2 550-2. Item 507 of the method includes application of a block mask to generate skip-via 570 and regular via 580. The skip-via 570 has a first height and the regular via 580 has a second height, where the first height is different from (greater than) the second height.

Once the two vias are formed (one skip-level via 470, 570, one regular via 480, 580), the rest of the processing is straightforward, as depicted in FIGS. 6-10, inclusive.

FIG. 6 shows an overview of a process flow 600, based on the examples described herein. FIG. 6 is similar to the process 300 shown in FIG. 3. At 601, the process includes top via formation, including formation of SV 670 and V1 630 above M1 610, which are formed by either process 400 or 500. As shown as part of item 601, there are no M2 power islands. At 602, the process includes application of a dielectric deposition 660 and CMP, the dielectric deposition 660 applied to M1 610, SV 670, and V1 630. At 603, the process includes an M2 signal line etch 661 of the dielectric deposition 660. At 604, the process includes fabrication of an M2 signal line metal fill 662. At 605, the process includes formation of an M2 signal line recess 663, the M2 signal line recess 663 being formed by removing a portion of the M2 signal line metal fill 662. Shown as part of item 605 is the formation of M2 power island 640. At 606, the process includes application of a dielectric deposition 664. The dielectric deposition 664 is shown in FIG. 6 as being above, and in contact with, the first dielectric deposition 660 and skip-via SV 670, as well as filling the recess 663. At 607, the process includes a V2M3 line/via lithography and etch, including an M3 etch (665-1 and 665-2) and a V2 etch 666. At 608, the process includes a V2M3 metal fill, including fabrication of M3 power islands 680-1 and 680-2 and V2 650.

Accordingly, disclosed and described herein is an interconnect stack structure, including signal and power lines, such that: two top-via structures are formed above the first metal level, with each via having a different height; where one via is subtractively-formed and extends to connect two non-adjacent levels of horizontal power line wiring; where one via is subtractively-formed and extends to connect to the next metal level; power staple vias have only one metal/metal interface located at the top of the power staple; intermediate metal lines—with power lines both above and below—are formed using a damascene process; and damascene signal lines are recessed and then covered with dielectric prior to the etching of the line and via above.

Thus, provided and described herein is a structure having a skip-level via as part of a power delivery network (PDN). Further, the examples described herein include integration of a skip-level via in a power staple with regular stacked vias in the adjacent power staple. Thus, the examples described herein involve use of a skip-level via.

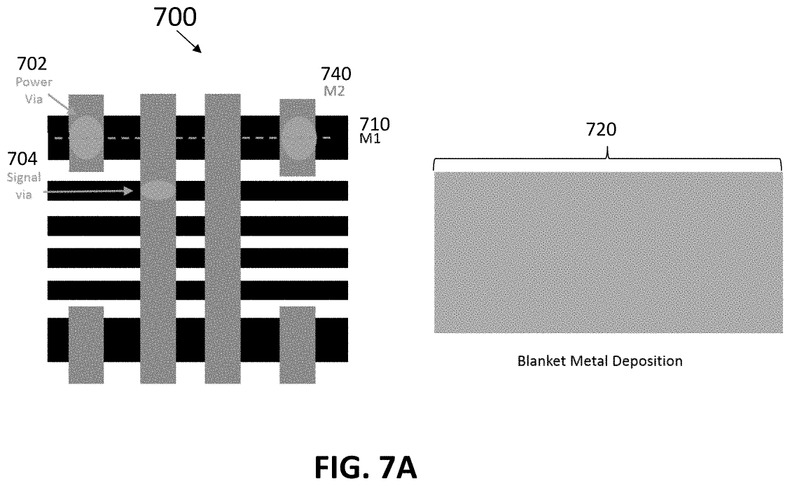

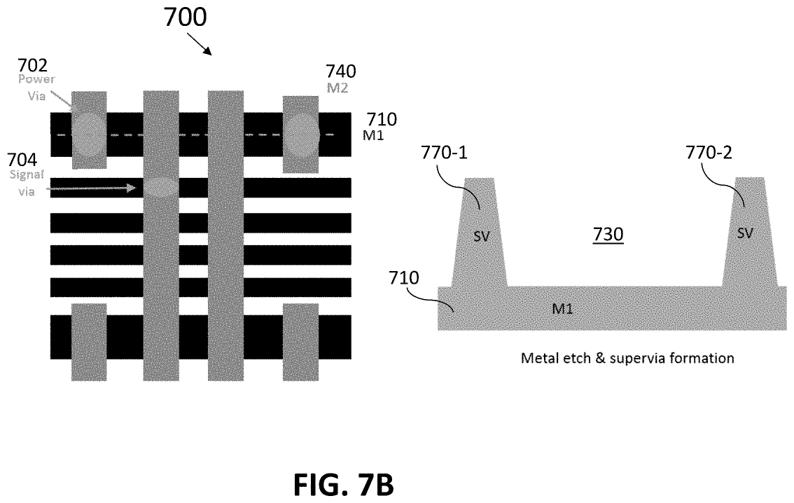

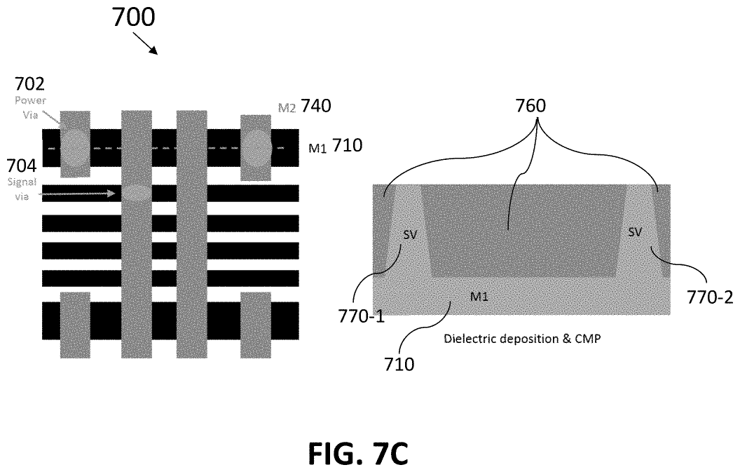

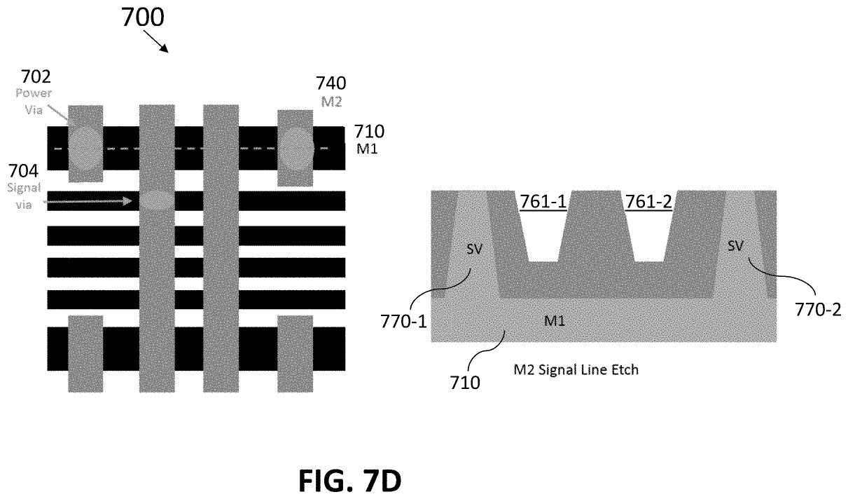

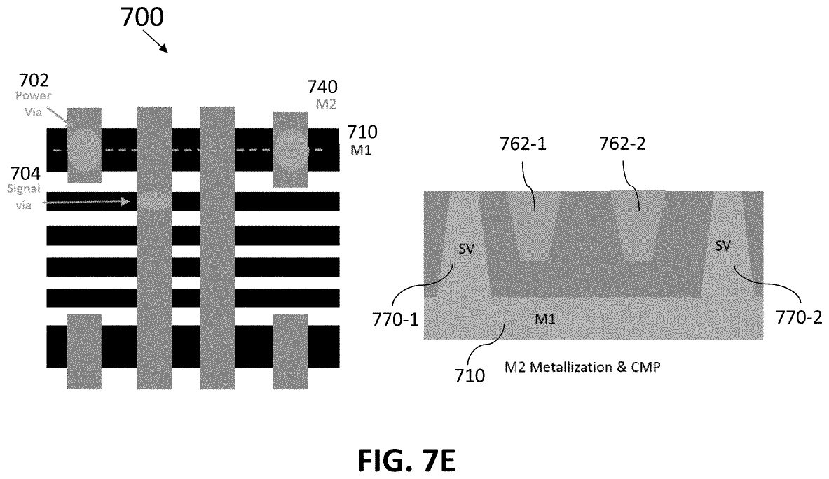

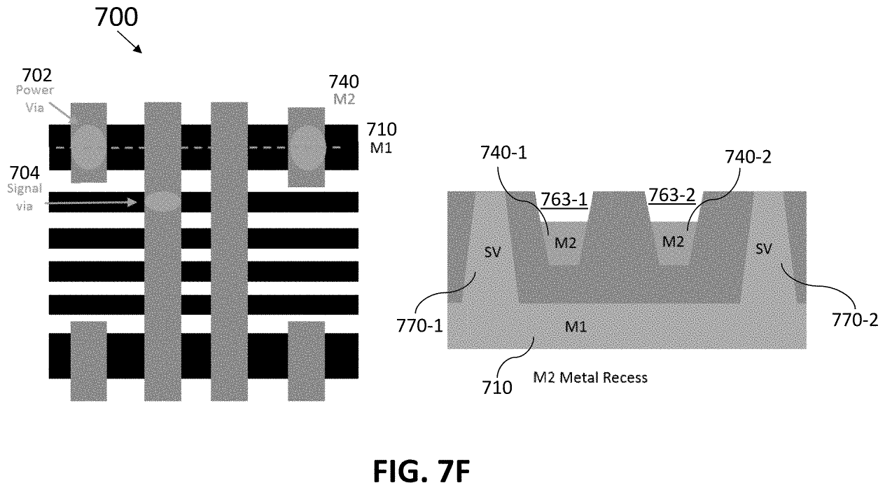

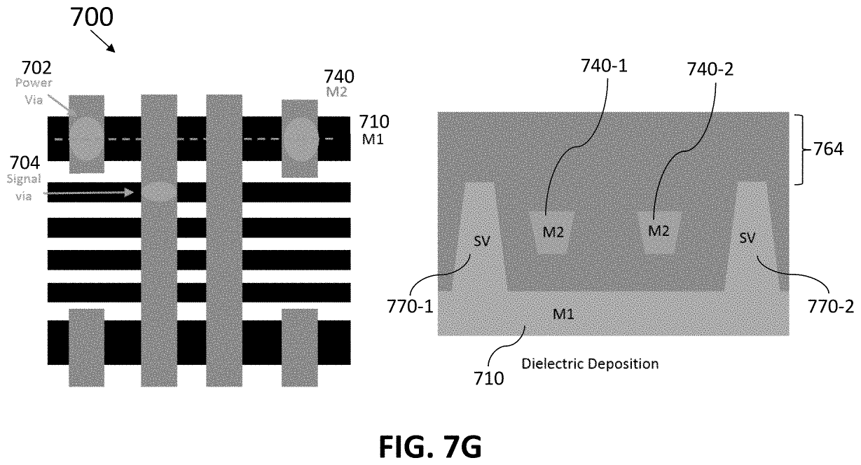

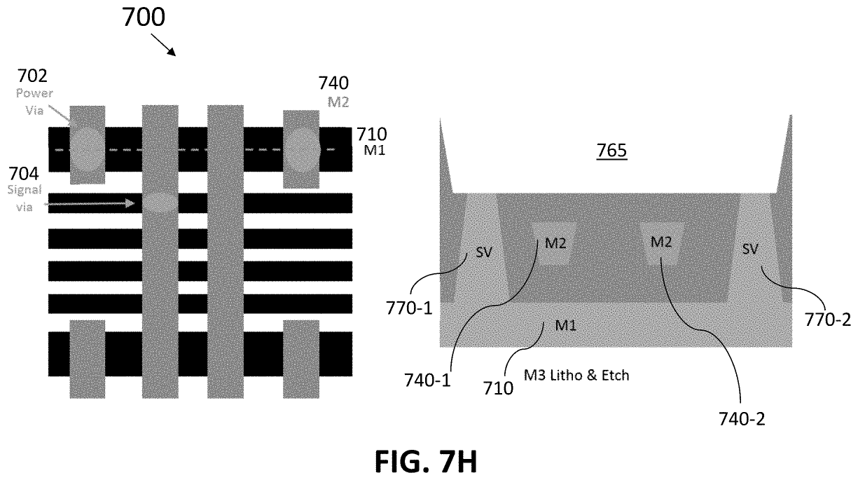

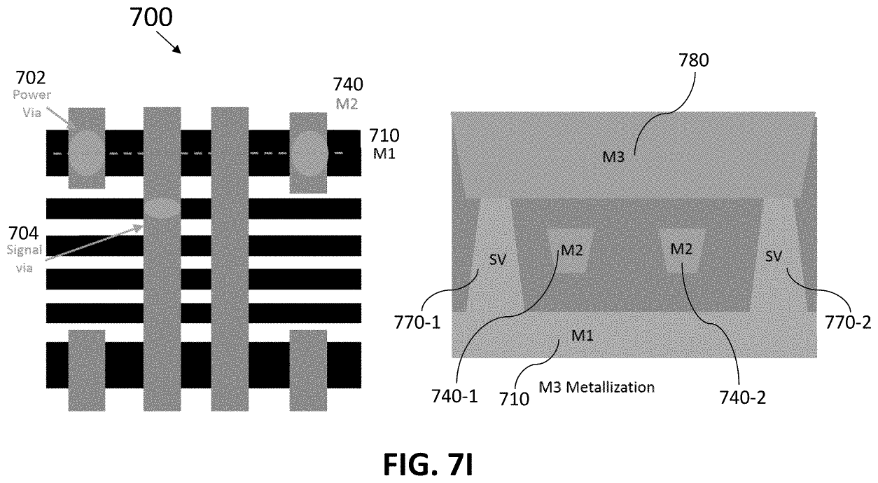

FIGS. 7-10 depict detailed process flow(s) along various cut directions in a sample layout.

FIGS. 7A-7I (inclusive) depict a detailed process flow 700 along an M1 power line.

FIG. 7A shows a portion of the process flow along the M1 power line 710, including application of a blanket metal deposition 720. Shown also in FIG. 7A is M2 power line 740, power via 702, and signal via 704. FIG. 7B shows a portion of the process flow along the M1 power line 710, including metal etch 730 and supervia (here, SV) formation, including formation of SV 770-1 and SV 770-2. Also shown is the formation of the M1 power island 710. FIG. 7C shows a portion of the process flow along the M1 power line 710, including application of dielectric deposition 760 and chemical mechanical polishing (CMP). As shown in FIG. 7C, the dielectric deposition 760 is applied to SV 770-1, M1 710, and SV 770-2. FIG. 7D shows a portion of the process flow along the M1 power line 710, including an M2 signal line etch within the dielectric deposition 760. Two M2 signal line etches are shown, 761-1 and 761-2. FIG. 7E shows a portion of the process flow along the M1 power line 710, including M2 metallization (762-1 within etch 761-1 and 762-2 within etch 761-2) and CMP. FIG. 7F shows a portion of the process flow along the M1 power line 710, including formation of M2 metal recesses. Two M2 metal recesses are shown including 763-1 and 763-2, which are formed by removing a portion of each of M2 metallizations 762-1 and 762-2. Two M2 power island metallizations are shown also, including M2 740-1 and M2 740-2. FIG. 7G shows a portion of the process flow along the M1 power line 710, including application of a second dielectric deposition 764 above and coming into contact with the supervias (770-1 and 770-2). FIG. 7H shows a portion of the process flow along the M1 power line 710, including an M3 lithography and etch 765 to remove a part of the second dielectric deposition 764. FIG. 7I shows a portion of the process flow along the M1 power line 710, including M3 metallization 780 within the M3 etch 765.

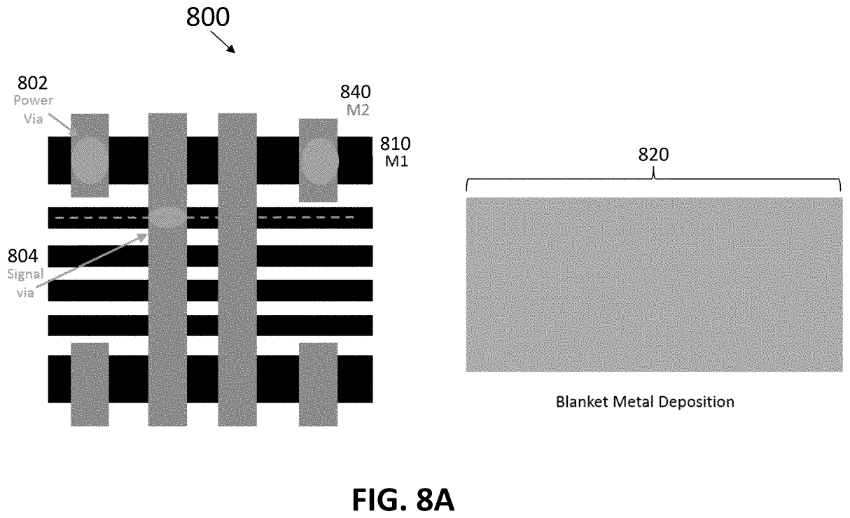

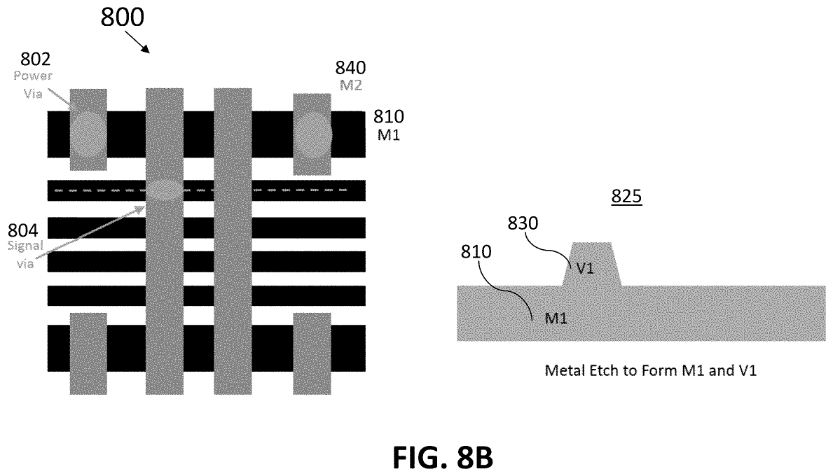

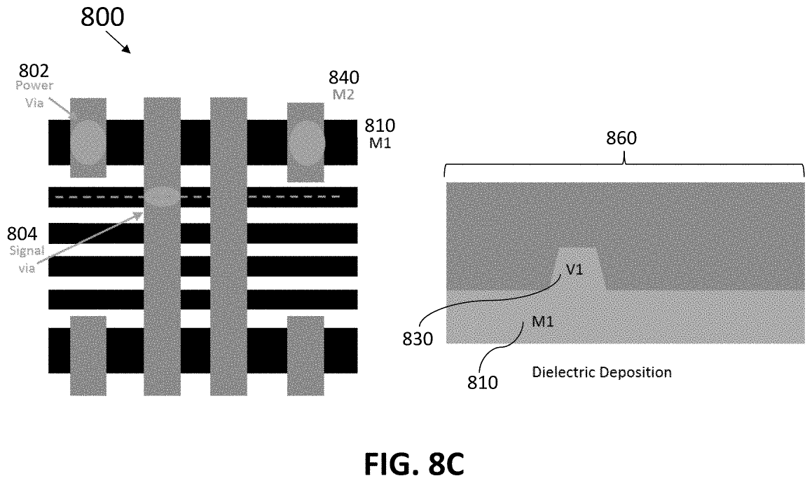

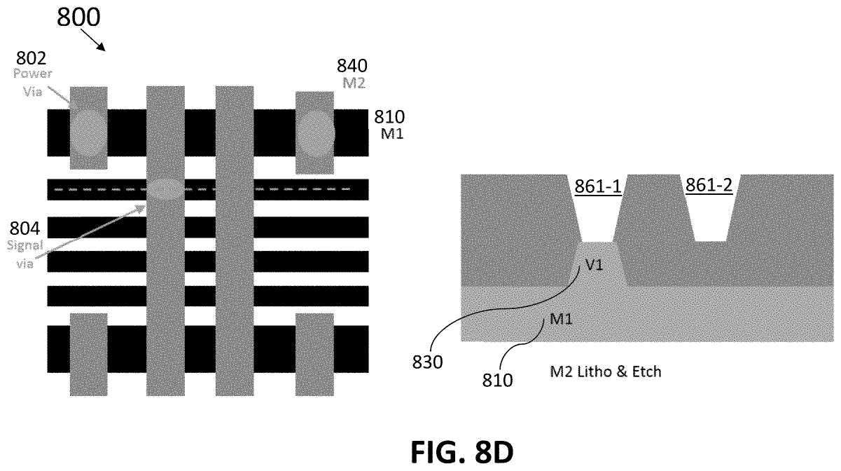

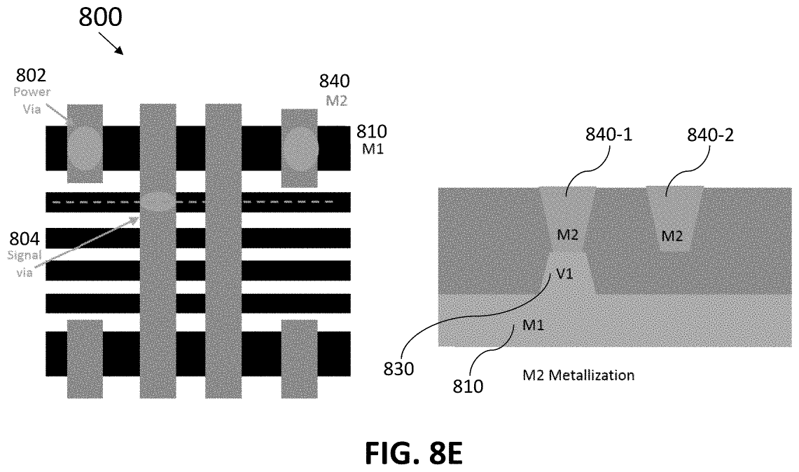

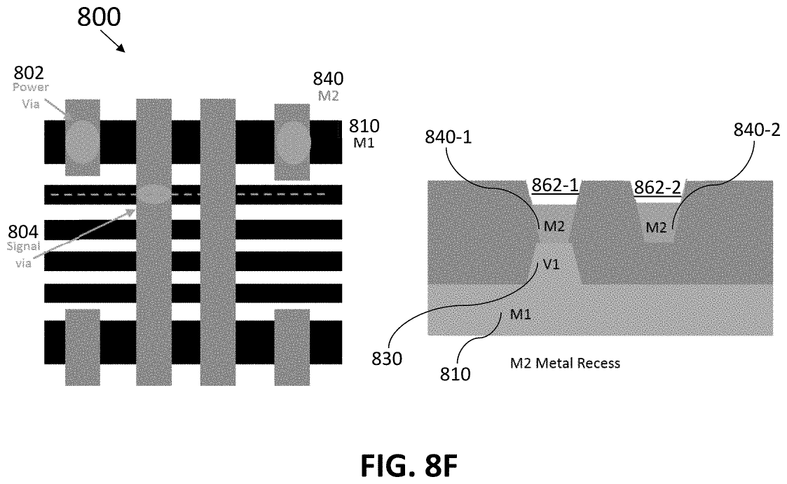

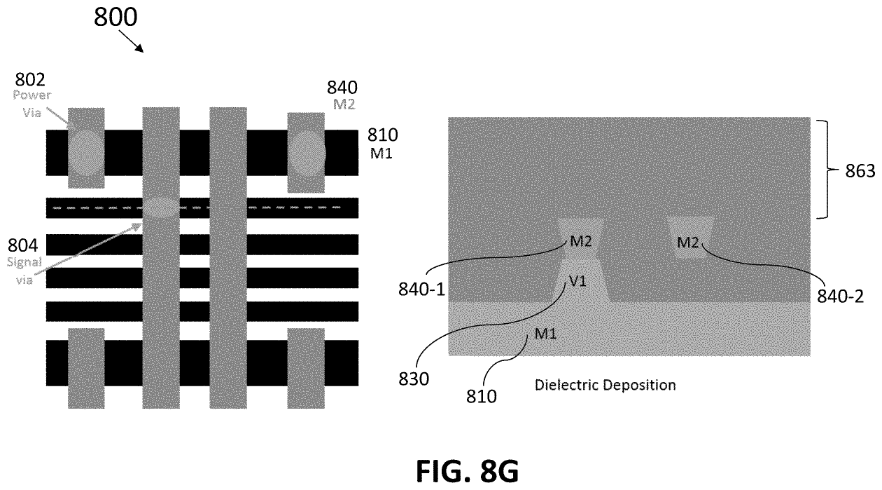

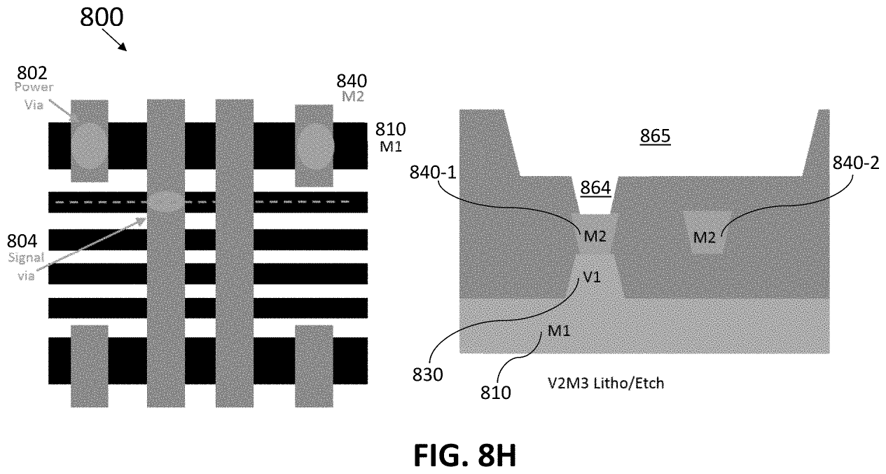

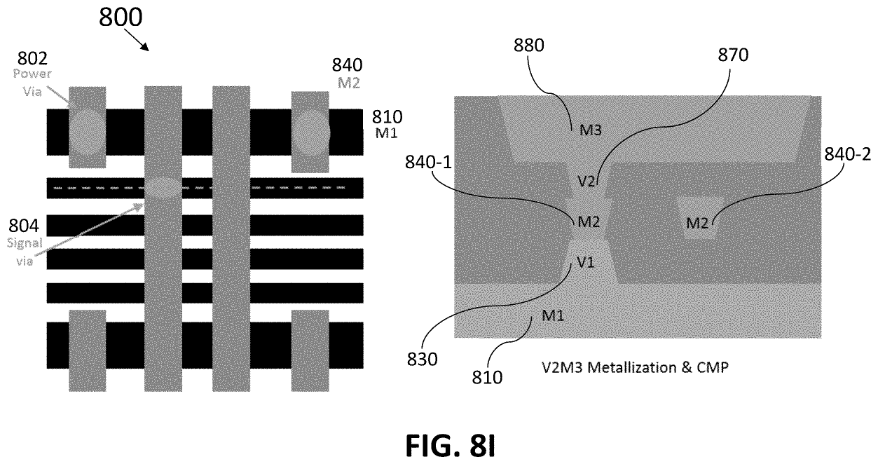

FIGS. 8A-8I (inclusive) depict a detailed process flow 800 along an M1 signal line.

FIG. 8A shows a portion of the process flow along the M1 signal line 810, including application of a blanket metal deposition 820. Shown also in FIG. 8A is M2 power line 840, power via 802, and signal via 804. FIG. 8B shows a portion of the process flow along the M1 signal line 810, including a metal etch 825 of the blanket metal deposition 820 to form M1 810 and V1 830. FIG. 8C shows a portion of the process flow along the M1 signal line 810, including application of a dielectric deposition 860 that comes in contact with surfaces of V1 830 and M1 810. FIG. 8D shows a portion of the process flow along the M1 signal line 810, including an M2 lithography and etch, which includes M2 etch 861-1 and M2 etch 861-2, each etched into the dielectric deposition 860. FIG. 8E shows a portion of the process flow along the M1 signal line 810, including M2 metallization to form M2 power island 840-1 within M2 etch 861-1 and M2 power island 840-2 within M2 etch 861-2. FIG. 8F shows a portion of the process flow along the M1 signal line 810, including generation of M2 metal recesses, including M2 recess 862-1 and M2 recess 862-2. The M2 recesses (862-1, 862-2) are formed by removing of some of the M2 metallization layer (840-1 and 840-2, respectively). FIG. 8G shows a portion of the process flow along the M1 signal line 810, including application of a second dielectric deposition 863 above the M2 metallization layer, including above M2 840-1 and M2 840-2. FIG. 8H shows a portion of the process flow along the M1 signal line 810, including a V2M3 lithography/etch. In particular, FIG. 8H shows V2 etch 864 etched into the dielectric deposition 863, and M3 etch 865 etched into the dielectric deposition 863. FIG. 8I shows a portion of the process flow along the M1 signal line 810, including V2M3 metallization and CMP. Thus, in FIG. 8I, via V2 870 is fabricated within the V2 etch 864, and power island M3 880 is fabricated within the M3 etch 865.

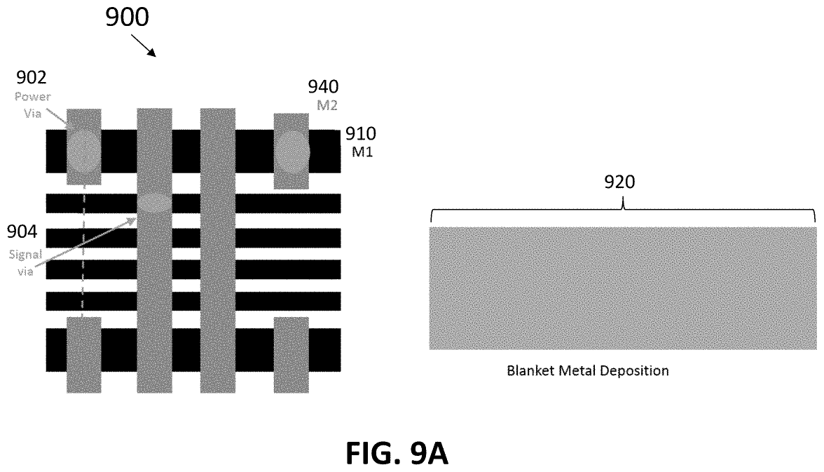

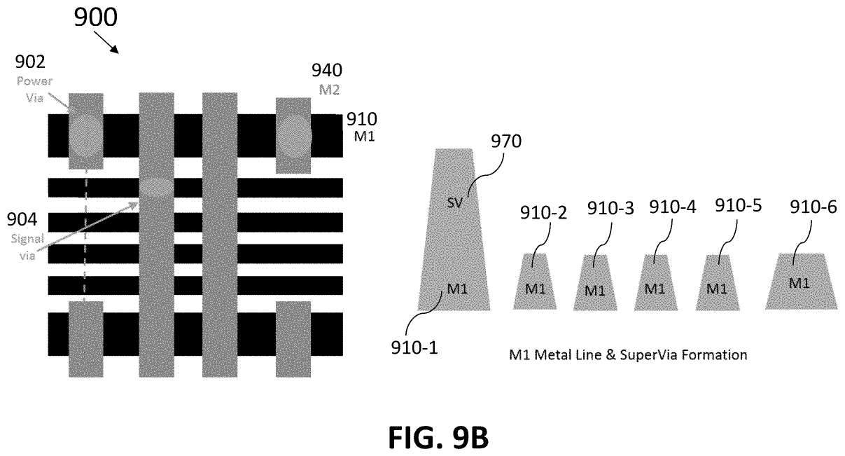

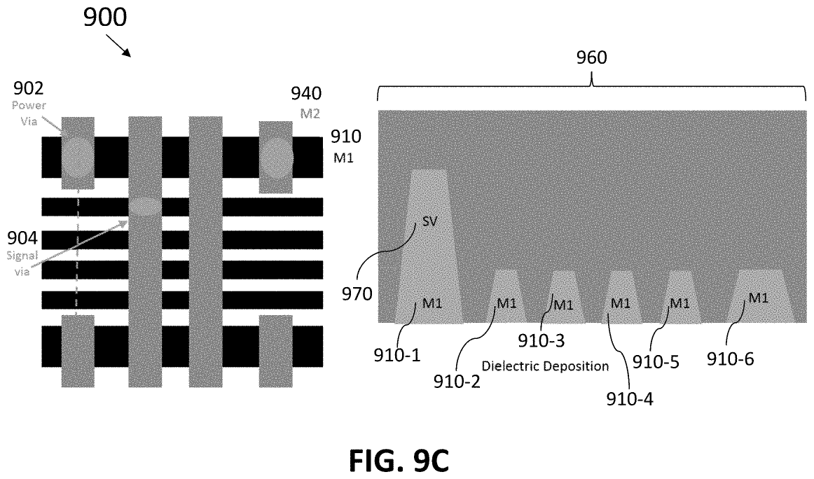

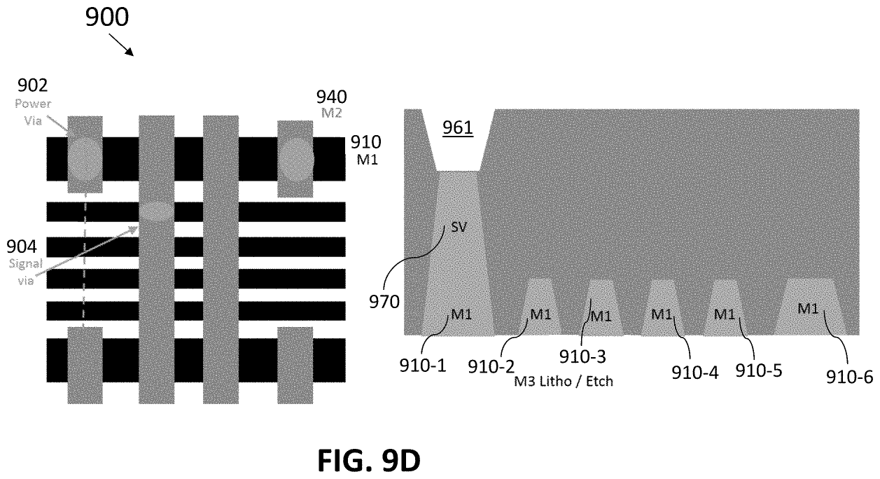

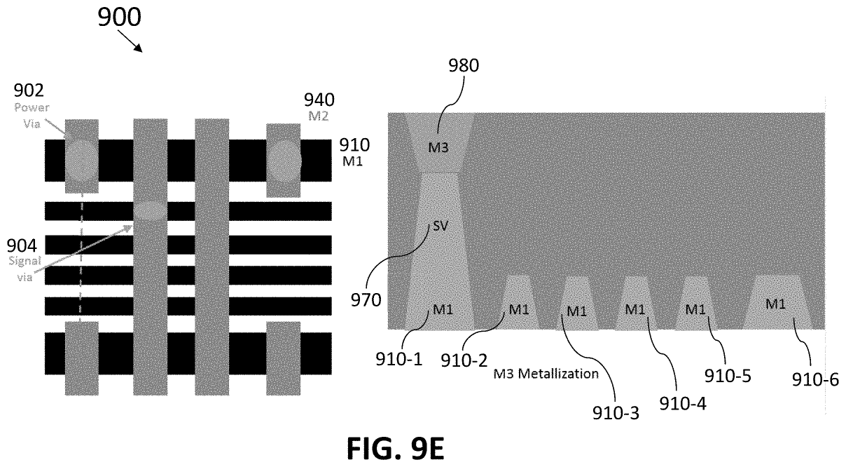

FIGS. 9A-9E (inclusive) depict a detailed process flow 900 along an M2 power island 940.

FIG. 9A shows a portion of the process flow along the M2 power island 940, including application of a blanket metal deposition 920. FIG. 9A further shows M1 power line 910, power via 902 and signal via 904. FIG. 9B shows a portion of the process flow along the M2 power island 940, including formation of an M1 metal line formed subtractively by removing a portion of the blanket metal deposition 920, and formation of supervia 970 formed subtractively by removing a portion of the blanket metal deposition 920. The M1 metal line includes M1 910-1, M1 910-2, M1 910-3, M1 910-4, M1 910-5, and M1 910-6. FIG. 9C shows a portion of the process flow along the M2 power island 940, including application of a dielectric deposition 960 to the structure, including to the supervia 970 and M1 metal line. FIG. 9D shows a portion of the process flow along the M2 power island 940, including M3 lithography/etch 961 that is etched by removing a portion of the dielectric deposition 960. FIG. 9E shows a portion of the process flow along the M2 power island 940, including fabrication of M3 metallization 980 within the M3 etch 961.

FIGS. 10A-10I (inclusive) depict a detailed process flow 1000 along an M2 signal line.

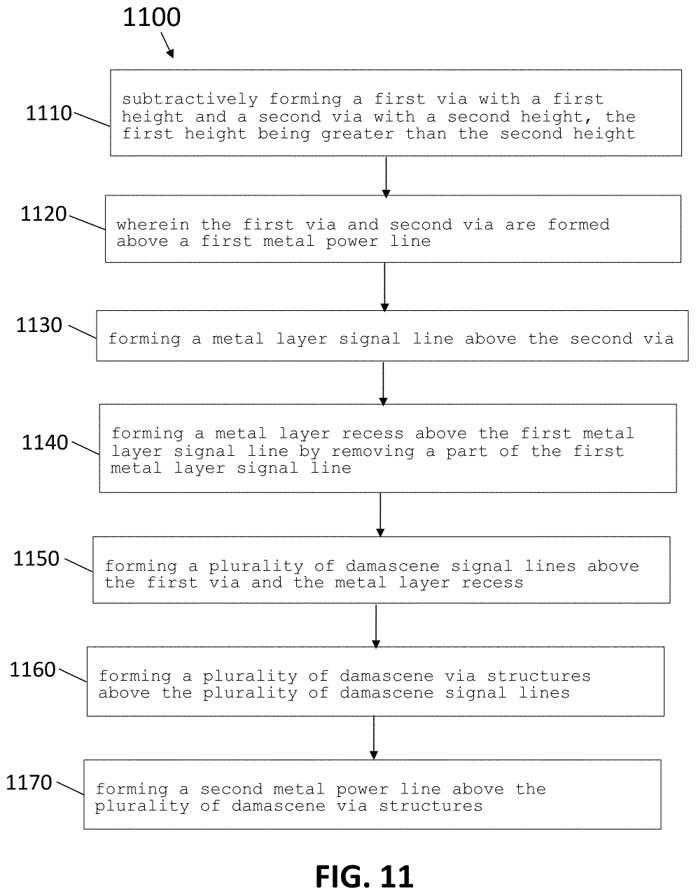

FIG. 10A shows a portion of a process flow along an M2 signal line 1040, including application of a blanket metal deposition 1020. Further shown in FIG. 10A is power via 1002, signal via 1004, and M1 power island 1010. FIG. 10B shows a portion of the process flow along the M2 signal line 1040, including formation of an M1 metal line and via V1 1030 subtractively formed by removing a portion of the blanket metal deposition 1020. As shown in FIG. 10B, M1 metal line includes M1 1010-1, M1 1010-2, M1 1010-3, M1 1010-4, M1 1010-5, and M1 1010-6. FIG. 100 shows a portion of the process flow along the M2 signal line 1040, including application of a dielectric deposition 1060 to the surfaces of the M1 metal line and V1 1030. FIG. 10D shows a portion of the process flow along the M2 signal line 1040, namely M2 lithography/etch 1061 formed as a result of etching a portion of the dielectric deposition 1060. FIG. 10E shows a portion of the process flow along the M2 signal line 1040, including M2 metallization 1040 within the M2 etch 1061. FIG. 10F shows a portion of the process flow along the M2 signal line 1040, including an M2 metal recess 1062 formed by removing parts of the M2 metallization 1040. FIG. 10G shows a portion of the process flow along the M2 signal line 1040, including application of a dielectric deposition 1063 formed above and coming into contact with the M2 metallization layer 1040. FIG. 10H shows a portion of the process flow along the M2 signal line 1040, including V2M3 dual damascene pattering. The damascene pattering includes formation of M3 etches 1064-1, 1064-2, 1064-3, and 1064-4, as well as formation of V2 etch 1065, both etches being performed within dielectric deposition 1063. FIG. 10I shows a portion of the process flow along the M2 signal line 1040, including V2M3 dual damascene metallization. The dual damascene metallization includes the fabrication of M3 1080-1, M3 1080-2, M3 1080-3, and M3 1080-4 within the M3 etches 1064-1, 1064-2, 1064-3, and 1064-4, respectively, as well as the fabrication of V2 1050 within V2 etch 1065.

FIG. 11 is a logic flow diagram that illustrates the operation of a method 1100, in accordance with the exemplary embodiments. At 1110, the method includes subtractively forming a first via with a first height and a second via with a second height, the first height being greater than the second height. At 1120, the method includes wherein the first via and second via are formed above a first metal power line. At 1130, the method includes forming a metal layer signal line above the second via. At 1140, the method includes forming a metal layer recess above the first metal layer signal line by removing a part of the first metal layer signal line. At 1150, the method includes forming a plurality of damascene signal lines above the first via and the metal layer recess. At 1160, the method includes forming a plurality of damascene via structures above the plurality of damascene signal lines. At 1170, the method includes forming a second metal power line above the plurality of damascene via structures.

The various blocks of method 1100 shown in FIG. 11 may be viewed as method steps, and/or as operations that result from operation of computer program code, and/or as a plurality of coupled logic circuit elements constructed to carry out the associated function(s).

Referring now to all the Figures, in one exemplary embodiment, an interconnect stack structure includes a first metal level of horizontal power line wiring; a second metal level of horizontal power line wiring; wherein the first metal level of horizontal power line wiring is not adjacent to the second metal level of horizontal power line wiring; two top-via structures comprising a first via and a second via, the two top-via structures being formed above the first metal level of horizontal power line wiring; wherein the first via has a first height and the second via has a second height, the first height being different from the second height; wherein the first via extends to connect the first metal level of horizontal power line wiring to the second metal level of horizontal power line wiring; wherein the second via extends to connect to the first metal level but not the second metal level; damascene intermediate metal lines between the first metal level of horizontal power line wiring and the second metal level of horizontal power line wiring; and damascene signal lines above the first via and the damascene intermediate metal lines.

The interconnect stack structure may further include wherein there is no power island between the first metal level and the second metal level. The interconnect stack structure may further include a plurality of power staple vias, wherein the power staple vias have only one metal to metal interface located at a top of a power staple. The interconnect stack structure may further include wherein the first via and the second via are subtractively formed. The interconnect stack structure may further include wherein the damascene signal lines are recessed and covered with dielectric prior to an etching of the damascene signal lines. The interconnect stack structure may further include a plurality of damascene via structures above the damascene signal lines. The interconnect stack structure may further include a signal via and a power via between the first metal level of horizontal power line wiring and the second metal level of horizontal power line wiring.

In another exemplary embodiment, a power delivery network structure includes a first power rail; a second power rail; wherein the first power rail and the second power rail are connected by a skip-level via; wherein there are no power islands between the first power rail and the second power rail; a plurality of damascene signal lines located between the first power rail and the second power rail; a plurality of top-via structures below the plurality of damascene signal lines and above the first power rail; wherein the plurality of top-via structures comprise at least the skip-level via; and a plurality of damascene via structures located above the plurality of damascene signal lines.

The power delivery network structure may further include wherein the first power rail and the second power rail are not adjacent. The power delivery network structure may further include wherein the skip-level via has a first height, and the plurality of top-via structures below the plurality of damascene signal lines comprise a second via having a second height, the first height being different from the second height. The power delivery network structure may further include wherein the second via is connected to the first power rail but not the second power rail. The power delivery network structure may further include wherein the skip-level via is subtractively formed. The power delivery network structure may further include a signal via and a power via between the first power rail and the second power rail.

In another exemplary embodiment, a method includes subtractively forming a first via with a first height and a second via with a second height, the first height being greater than the second height; wherein the first via and second via are formed above a first metal power line; forming a metal layer signal line above the second via; forming a metal layer recess above the first metal layer signal line by removing a part of the first metal layer signal line; forming a plurality of damascene signal lines above the first via and the metal layer recess; forming a plurality of damascene via structures above the plurality of damascene signal lines; and forming a second metal power line above the plurality of damascene via structures.

The method may further include wherein the first via connects the first metal power line to the second metal power line, and the second via is connected to the first metal power line but not the second metal power line. The method may further include wherein there is no power island between the first metal power line and the second metal power line. The method may further include wherein the first via with the first height and the second via with the second height are subtractively formed using a method comprising: applying a first hard mask to a blanket metal deposition, the first hard mask being for a first set of at least one power via and a metal power island; applying a second hard mask to a dielectric scaffold deposition, the second hard mask being for a second set of at least one power via and signal via; applying a first dielectric etch to the dielectric scaffold deposition to remove a portion of the dielectric scaffold deposition between the first set and second set; and applying a second dielectric etch to the dielectric scaffold deposition to remove a portion of the dielectric scaffold deposition above the power via of the second set. The method may further include removing the first hard mask and the second hard mask. The method may further include wherein the metal power island has the substantially the same dimensions as the at least one power via within the first set. The method may further include wherein the first via with the first height and the second via with the second height are subtractively formed using a method comprising: applying a hard mask to a blanket metal deposition, the hard mask being for a first set of at least one first set power via and a first metal power island, and for a second set of at least one second set power via and a second metal power island; applying a first block mask to the first set and to an organic planarization layer deposition; and applying a second block mask to remove a via of the at least one second set power via and the second metal power island.

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments. It will be understood that when an element as a layer, region, or substrate is referred to as being “on” or “over” another element, it can be directly on the other element or intervening elements may also be present. In contrast, when an element is referred to as being “directly on” or “directly” over another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The description of the present invention has been presented for purposes of illustration and description, but is not intended to be exhaustive or limiting in the form disclosed. Many modifications and variations will be apparent to those of ordinary skill in the art without departing from the scope of the invention. The embodiments were chosen and described in order to best explain the principles of the invention and the practical applications, and to enable others of ordinary skill in the art to understand the invention for various embodiments with various modifications as are suited to the particular uses contemplated.

What is claimed is:

1. An interconnect stack structure, comprising:
a first metal level of horizontal power line wiring;
a second metal level of horizontal power line wiring;
wherein the first metal level of horizontal power line wiring is not adjacent to the second metal level of horizontal power line wiring;
two top-via structures comprising a first via and a second via, the two top-via structures being formed above the first metal level of horizontal power line wiring;
wherein the first via has a first height and the second via has a second height, the first height being different from the second height;
wherein the first via extends to connect the first metal level of horizontal power line wiring to the second metal level of horizontal power line wiring;
wherein the second via extends to connect to the first metal level but not the second metal level;
damascene intermediate metal lines between the first metal level of horizontal power line wiring and the second metal level of horizontal power line wiring; and
damascene signal lines above the first via and the damascene intermediate metal lines.

2. The interconnect stack structure of claim 1, wherein there is no power island between the first metal level and the second metal level.

3. The interconnect stack structure of claim 1, further comprising: a plurality of power staple vias, wherein the power staple vias have only one metal to metal interface located at a top of a power staple.

4. The interconnect stack structure of claim 1, wherein the first via and the second via are subtractively formed.

5. The interconnect stack structure of claim 1, wherein the damascene signal lines are recessed and covered with dielectric prior to an etching of the damascene signal lines.

6. The interconnect stack structure of claim 1, further comprising: a plurality of damascene via structures above the damascene signal lines.

7. The interconnect stack structure of claim 1, further comprising: a signal via and a power via between the first metal level of horizontal power line wiring and the second metal level of horizontal power line wiring.

8. A power delivery network structure, comprising:
a first power rail;
a second power rail;
wherein the first power rail and the second power rail are connected by a skip-level via;
wherein there are no power islands between the first power rail and the second power rail;
a plurality of damascene signal lines located between the first power rail and the second power rail;
a plurality of top-via structures below the plurality of damascene signal lines and above the first power rail;
wherein the plurality of top-via structures comprise at least the skip-level via; and
a plurality of damascene via structures located above the plurality of damascene signal lines.

9. The power delivery network structure of claim 8, wherein the first power rail and the second power rail are not adjacent.

10. The power delivery network structure of claim 8, wherein the skip-level via has a first height, and the plurality of top-via structures below the plurality of damascene signal lines comprise a second via having a second height, the first height being different from the second height.

11. The power delivery network structure of claim 10, wherein the second via is connected to the first power rail but not the second power rail.

12. The power delivery network structure of claim 8, wherein the skip-level via is subtractively formed.

13. The power delivery network structure of claim 8, further comprising: a signal via and a power via between the first power rail and the second power rail.

14. A method, comprising:
subtractively forming a first via with a first height and a second via with a second height, the first height being greater than the second height;
wherein the first via and second via are formed above a first metal power line;
forming a metal layer signal line above the second via;
forming a metal layer recess above the first metal layer signal line by removing a part of the first metal layer signal line;
forming a plurality of damascene signal lines above the first via and the metal layer recess;
forming a plurality of damascene via structures above the plurality of damascene signal lines; and
forming a second metal power line above the plurality of damascene via structures.

15. The method of claim 14, wherein the first via connects the first metal power line to the second metal power line, and the second via is connected to the first metal power line but not the second metal power line.

16. The method of claim 14, wherein there is no power island between the first metal power line and the second metal power line.

17. The method of claim 14, wherein the first via with the first height and the second via with the second height are subtractively formed using a method comprising:
applying a first hard mask to a blanket metal deposition, the first hard mask being for a first set of at least one power via and a metal power island;
applying a second hard mask to a dielectric scaffold deposition, the second hard mask being for a second set of at least one power via and signal via;
applying a first dielectric etch to the dielectric scaffold deposition to remove a portion of the dielectric scaffold deposition between the first set and second set; and
applying a second dielectric etch to the dielectric scaffold deposition to remove a portion of the dielectric scaffold deposition above the power via of the second set.

18. The method of claim 17, further comprising removing the first hard mask and the second hard mask.

19. The method of claim 17, wherein the metal power island has the substantially the same dimensions as the at least one power via within the first set.

20. The method of claim 14, wherein the first via with the first height and the second via with the second height are subtractively formed using a method comprising:
applying a hard mask to a blanket metal deposition, the hard mask being for a first set of at least one first set power via and a first metal power island, and for a second set of at least one second set power via and a second metal power island;
applying a first block mask to the first set and to an organic planarization layer deposition; and
applying a second block mask to remove a via of the at least one second set power via and the second metal power island.
